(19) United States
(12) Patent Application Publication
(10) Pub. No.: US 2004/0207044 A1
(43) Pub. Date: Oct. 21, 2004

(54) Laser trimming with phase shifters

(76) Inventors: Paul A. Ruggerio, Peabody, MA (US); David Bain, Castleroberts (IE); Gilbert Huppert, Stoneham, MA (US); Edward F. Gleason, Lexington, MA (US); Michael D. Delaus, Andover, MA (US)

Correspondence Address: Samuels, Gauthier & Stevens, LLP, Suite 3300, 225 Franklin Street, Boston, MA, 02110, US

(21) Appl. No.: 10/418,535

(22) Filed: Apr. 18, 2003

(51) Int. Cl. H01L 29/00

(52) U.S. Cl. 257/536

(57) ABSTRACT

An improved laser trimming technique allows for a portion of the laser energy to always be on a path length for creating a constructive node independently of the oxide thickness. This improvement is accomplished by forming steps in the reflective silicon that ensure constructive nodes (or prevents the formation of destructive nodes) at the thin film plane. The steps are formed using any of the following techniques: shallow trench isolation, a separate etch step, or LOCOS.

### BACKGROUND OF THE INVENTION

The invention relates to the field of laser trimming and, in particular, to a laser trimming method that is insensitive to oxide thickness control or planarization.

Traditionally, laser trimming techniques are employed for trimming thin film resistors for adjusting device parameters and making precision resistor networks. This technique uses a laser to trim SiCr resistors, possessing a resistivity range from 100 to 2000 Ω/sq., depending on the process. This is accomplished by using a pulse laser at λ=10620 A with sufficient energy per pulse to create a kerf cut from overlapping stepped pulses. The energy level needs to be controlled to ensure sufficient trims without creating excessive damage to the under and overlying oxides or passivation. This isn't as much of a problem at 100 Ω/sq., where there is more absorption, than there is at 1000 Ω/sq., where there is more transmission. When there is sufficient transmission, it is necessary to ensure that constructive waves rather than destructive waves form at the resistor trim plane.

FIG. 1 illustrates a constructive and destructive wave occurring in the wave resistor trim plane 102. The laser wave 104 reflects from the SiO₂—Si interface 106 with sufficient energy due to the high index of refraction of the Si in comparison to the SiO₂ film. The two waves depicted by the incident wave 104 and the reflected wave 108 meet at the resistor plane 102 to form a constructive node. The oxide (SiO₂) thickness is a critical parameter, as this height determines if the incident 104 and reflected wave 108 meet in a constructive way at the resistor plane 102. For example, the incident beam 104 and reflected beam 108 meet in a constructive way if the oxide thickness is equal to h1. On the other hand if the thickness of the oxide is h2, the incident 104 and reflected beam 108 meet in a destructive manner. Thus, prior art techniques attempt to control the thickness of the oxide layer to be as close to h1 as possible.

The oxide thickness target needs to be equal to at a quarter wave of an odd multiple of the wavelength in oxide. The range from the target thickness should be equal to ±λ/16 for λ in oxide. In most cases, λ in oxide=λ₀ n₀/n₁, or λ=10620 A 1.0/1.45=7324 A. Therefore, the thickness control needs to be 7324 A/16=±460 A. In the worst-case scenario, the thickness control needs to be ±λ/8 or ±920 A.

Oxide thickness control has been feasible for all Analog Devices processes until it has become necessary to utilize Chemical Mechanical Polishing to planarize the wafer surface. The CMP process creates planar surfaces with thickness uniformity equal to or less than 5%, but it cannot maintain absolute thickness to meet trim specifications. This problem increases with the number of CMP steps.

A major problem encountered in such prior art techniques is that is has proven to be more difficult to set the thickness of the oxide, especially when oxides are planarized. The following reference is representative of the prior art as it teaches the use of carefully controlling all the oxides between the substrate and the material being trimmed. Additionally, prior art methods include placing a reflective plate just prior to the last oxide being deposited and the thin film material being trimmed to eliminate the reflective wave.

The U.S. patent to Morrison (U.S. Pat. No. 6,259,151 B1) provides for using a barrier refractive or anti-reflective layer to improve laser trim characteristics of thin film resistors. Morrison discloses an improvement to laser trimming with the addition of a refractory layer, and a dielectric layer, both below a laser trimmed resistor film. A precision resistor of NiCr or SiCr has a refractive and thermal barrier layer beneath the resistor. The refractive barrier is a layer of refractive metal. The refractory metal prevents the incident laser beam of a laser trimmer from penetrating lower layers of the device. This setup provides for a quality trim by eliminating laser energy interaction with device silicon and bond oxide layers below the barrier refractive layer. Since such silicon and bond oxide lower layers can no longer affect the local intensity of the laser energy, the uniformity of laser trim and kerf is improved. Thus, unwanted reflections and refractions caused by lower layers are avoided. The reflective barrier layer is a material selected from the group consisting of tungsten, titanium, molybdenum, TiSi₂^{13,14}, CoSi₂¹⁵, MoSi₂, TaSi₂, TaSi₂, and WSi₂.

Whatever the precise merits, features, and advantages of the above-mentioned prior art techniques, none of them achieves or fulfills the purposes of the present invention.

### SUMMARY OF THE INVENTION

The present invention provides for a laser trimming technique using phase shifters, wherein the disclosed technique allows for a portion of the laser energy to always be on a path length for creating a constructive node (or preventing the formation of a destructive node) independently of the oxide thickness. This is accomplished by forming steps in the reflective silicon that ensures a laser path substantially equal to an odd multiple of a quarter wavelength in oxide. One or two steps are shown to be practical and cost effective. A one step could be achieved with one extra mask or with no additional mask by using the (shallow trench isolation) STI mask and shifting the STI depth to the nearest node. A two step could be done with two or one extra mask.

Additionally, the present invention also provides for a semiconductor device (wherein the parameters associated with the semiconductor are adjustable) comprising: a substrate (e.g., Si) for reflecting incident trimming laser waves, an integrated circuit formed in the substrate, a dielectric layer (e.g., SiO₂) disposed over the substrate, and a trimmable thin film layer (e.g., thin film resistor layer such as a SiCr or NiCr layer) disposed over the dielectric layer. A plurality of steps are disposed on the substrate such that the incident and reflected trimming laser waves form constructive nodes (or prevent the formation of destructive nodes) at the trimmable thin film layer. The steps are formed using any of the following techniques: shallow trench isolation, a separate etch step, or LOCOS.

### BRIEF DESCRIPTION OF THE DRAWINGS

FIG. 1 illustrates a constructive and destructive wave occurring in the wave resistor trim plane.

FIG. 2 illustrates the present invention's no step, one step, and two step laser trimming processes.

FIG. 3 illustrates in detail the laser trimming technique of the present invention based upon a one step process.

FIG. 4 illustrates the structure of thin film resistors made in accordance with the present invention.

FIG. 5 illustrates oxide stack control for trimming thin film resistors.

FIG. 6 illustrates a graph of the laser trim field (as a sinusoidal function) used in silicon assisted trimming that removes sensitivity to oxide stack thickness.

FIG. 7 illustrates a structure formed via the LOCOS oxidation sequence.

FIGS. 8a-c collectively illustrate the LOCOS oxide isolation technique that forms oxide step by selectively growing a thermal oxide.

FIG. 9 illustrates the various geometries derived using the present invention's laser trimming process.

FIGS. 10a-c collectively illustrate the graphs of Kerf width versus Tox for various combinations of the geometries of FIG. 9.

FIG. 11 illustrates a table providing the Kerf width and Tox data corresponding to FIGS. 10a-c.

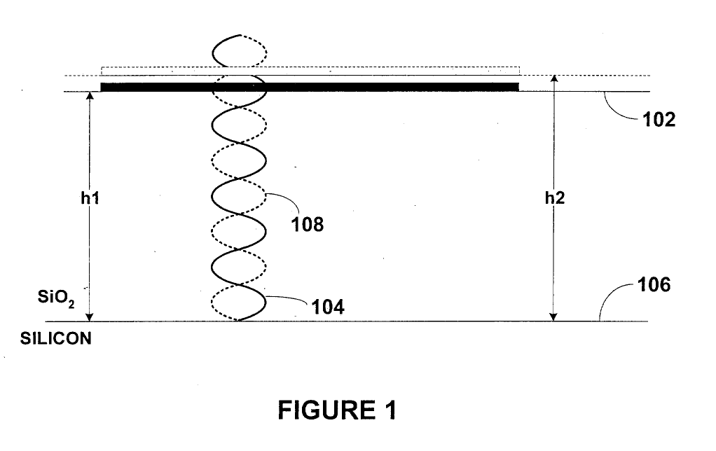

### DETAILED DESCRIPTION OF THE INVENTION

Although the present invention has been shown and described with respect to several preferred embodiments thereof, various changes, omissions, and additions to the form and detail thereof, may be made therein, without departing from the spirit and scope of the invention.

The laser path shifter technique of the present invention allows for a portion of the laser energy to always be on a path length for creating a constructive node independently of the oxide thickness. This is done by etching steps in the reflective silicon that would ensure a laser path substantially equal to an odd multiple of a quarter wavelength in oxide. An ideal situation would be to have an infinite number of steps, but this is not practical; and the more steps one employs, the lower the total energy at the resistor plane. Therefore, one or two steps are practical and cost effective. A one step is achieved with one extra mask or with no additional mask by using the shallow trench isolation (STI) mask and shifting the STI depth to the nearest node. A two-step is achieved with two or one extra mask.

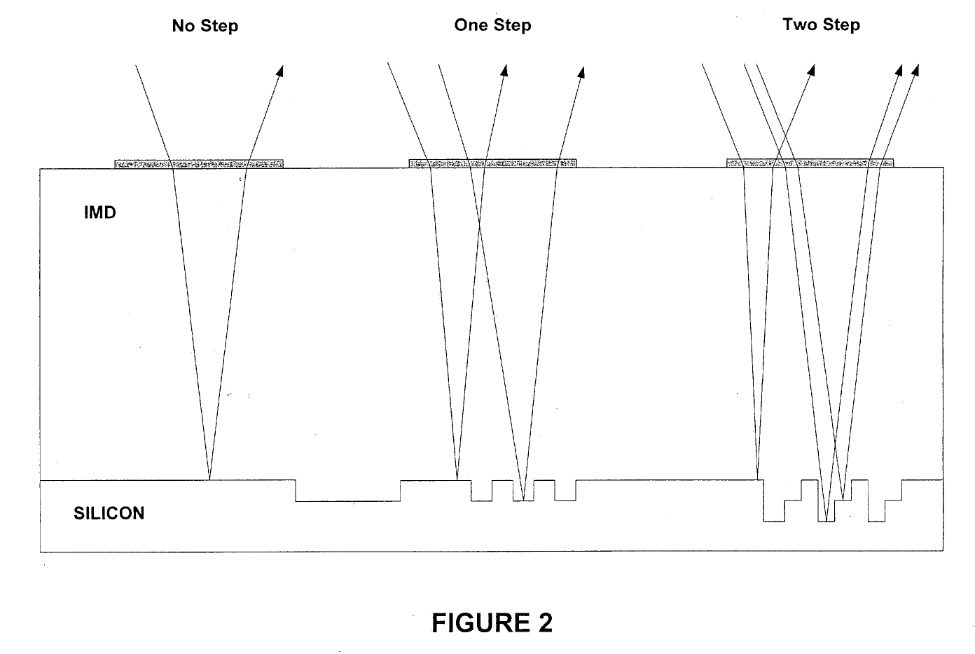

FIG. 2 illustrates the no step, one step, and two step processes. The no step would use the least amount of laser energy if the IMD thickness were at its optimum node. It would also be the only one that would not trim if the node were completely out of phase. In a bimodal situation, the one step would require less energy than the two step, but in reality the IMD thickness is never precisely on target; therefore, the advantage would go to the two step design even though it requires more energy. This scheme would also work well in conjunction with a more absorbing film.

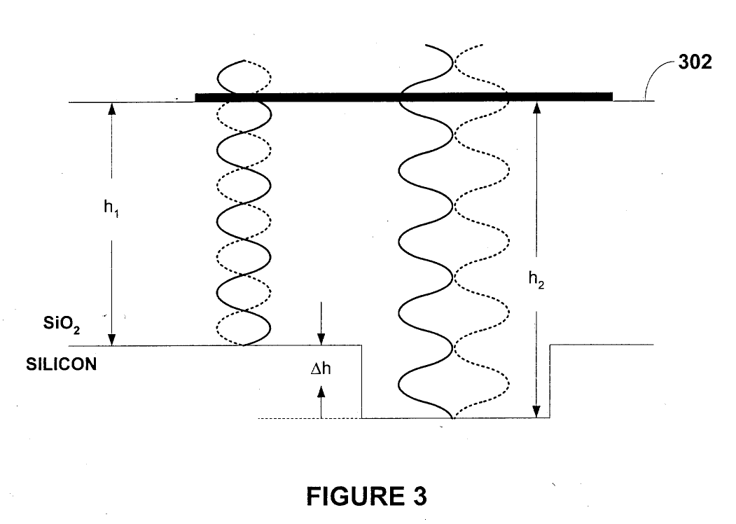

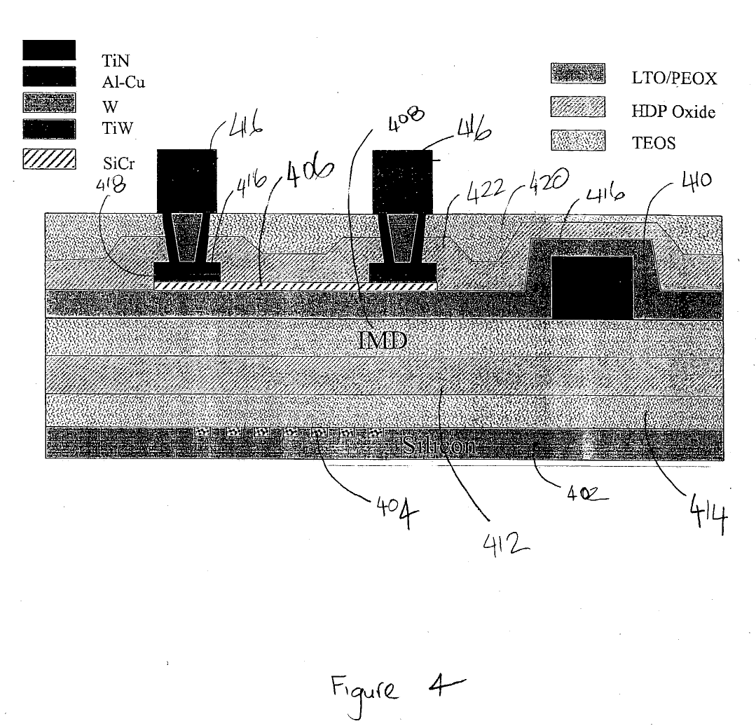

FIG. 3 illustrates the laser trimming technique of the present invention based upon a one step process. The laser path on the left results in a cancellation node at the thin film plane 302. The height h1 is such that the reflected wave cancels the energy of the incident wave. The laser path on the right results in a constructive node at the thin film plane. It should be noted that the choice of height h2 is such that the reflected wave forms a constructive node at the thin film plane 302. Based on the technique of the present invention, the steps are created in the silicon which is equal to Δh=h2−h1. The pitch of the steps is smaller than the laser beam effective spot size.

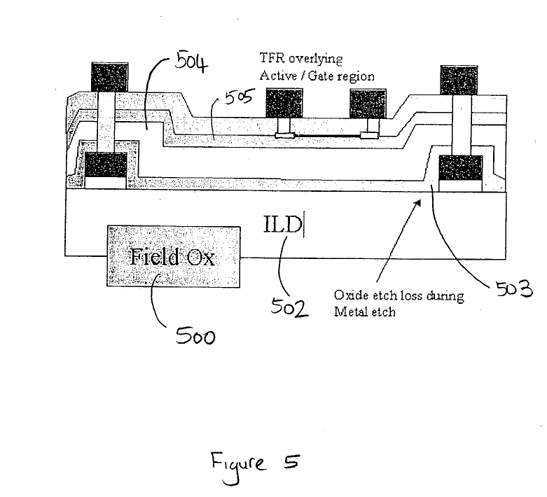

FIG. 4 illustrates the structure of thin film resistors made in accordance with the present invention. Silicon layer 402 comprises a plurality of steps 404, wherein such steps provide for a cancellation node at the thin film plane of SiCr 406. Disposed between the thin film plane 406 and the silicon layer 402 is an IMD layer 408 and a series of oxide layers (LTO/PEOX layer 410, HDP oxide layer 412, and a TEOS layer 414). Also shown in FIG. 4 are additional oxide layers of TEOS 420 and HDP Oxide 422 and barrier metal layers of TiN 416 and TiW 418.

FIG. 5 illustrates oxide stack control for trimming thin film resistors. The best choice oxide stack proposed for the 0.6 μm based CMOS/DMOS processes is as follows: The traditional field oxide 500 is removed from under the thin film resistor (tfr) to remove the variation in the oxide stack due to the various post field oxide wet etch chemistries, which add a few hundred Angstroms of variability from lot to lot and across a wafer. After a SPACER ETCH (Tox off 0 A), the variation in the ILD 502 (dielectric stack below met1 503) and a large part of the IMD 504 (dielectric stack between met1 503 and met2 505) need to be considered. In this specific example, the optimum center of the population focused around 16.1 KA (16.4 KA with a 300 A Rfetch immediately prior to SiCr deposit to further reduce surface roughness).

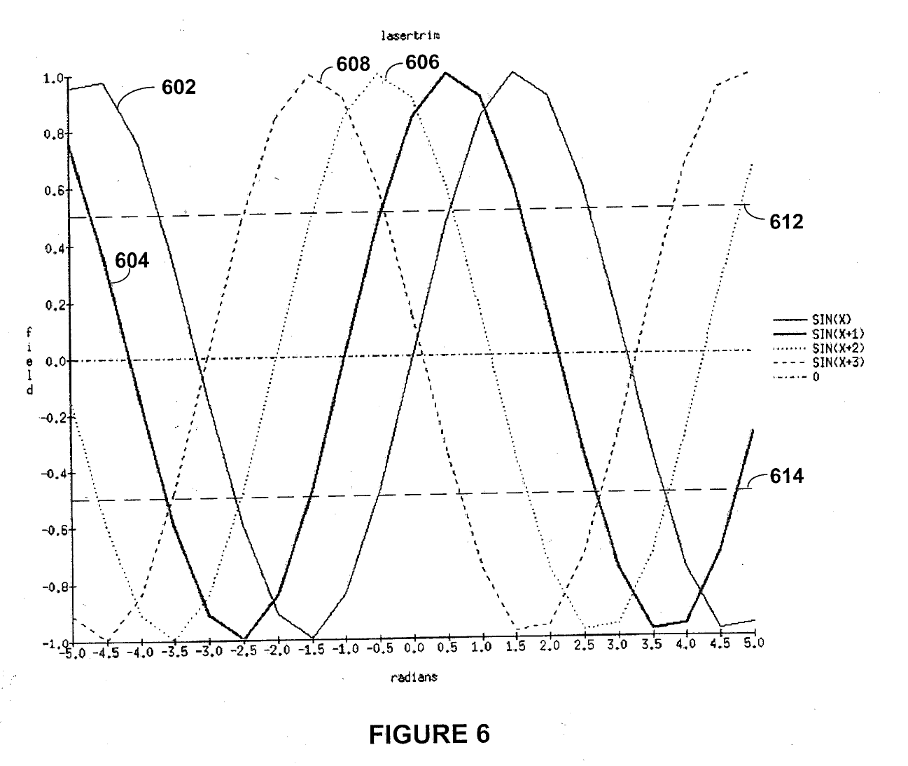

FIG. 6 illustrates a graph of the laser trim field (as a sinusoidal function) used in silicon assisted trimming that removes sensitivity to oxide stack thickness. FIG. 6 shows shifted versions of the same field (sin(x) 602, sin(x+1) 604, sin(X+2) 606, sin(x+3) 608). The basic idea of silicon step assisted trimming is to get two oxide thickness stacks under the tfr at the same time-based ¼ wavelength apart. Successful trimming takes place when the energy fields are approximately above ±50% as shown by lines 612 and 614. This threshold implies that we need to be offset by ¼ wavelength (1815 A) between our two Si surfaces in order to guarantee trimmability regardless of the overall stack height.

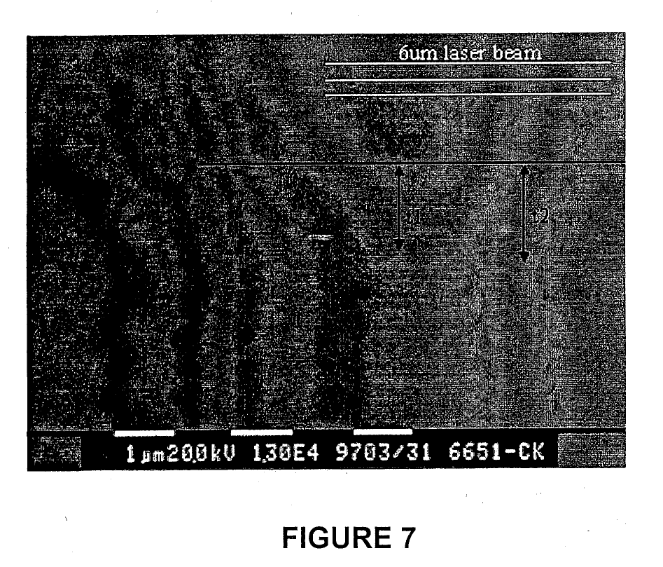

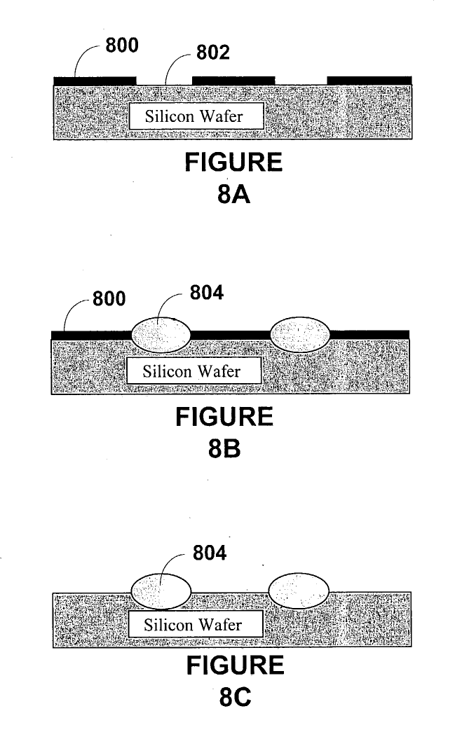

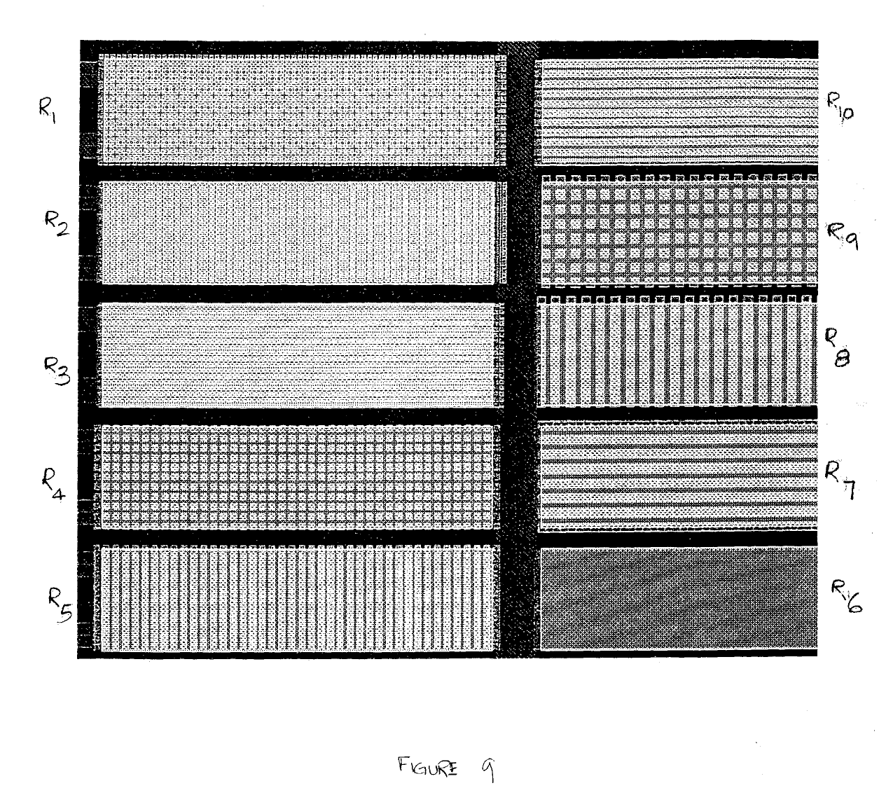

FIG. 7 illustrates a structure formed via the LOCOS oxidation sequence. This is achieved using the std LOCOS ox/active area height difference, assuming near perfect planarisation by subsequent BPTEOS reflow and Spin-on-Glass (SOG) spin etchback before the SiCr film is deposited. The LOCOS oxidation sequence and subsequent sacrificial oxidations/gate oxidation, etc., determine fixed relationship between t1 and t2—provided the fixed relationship is of the order of 1800 A for Analog's CMOS process, which equates to about ¼ wavelength of the laser in SiO2. Therefore, we would expect successful trimming in the region with overlaying Tox=t1 when the overlying Tox=t2 is at a point of destructive interference—and vice versa.

FIGS. 8a-c collectively illustrate the LOCOS oxide isolation technique that forms oxide step by selectively growing a thermal oxide. FIG. 8a illustrates the step wherein a deposited silicon nitride 800 has been imaged and etched to form windows 802 where an oxide isolation area is to be formed. FIG. 8b illustrates the step wherein a thermal oxide 804 is grown from the exposed Silicon through the silicon nitride windows. This oxide growth consumes silicon, which forms steps. FIG. 8c illustrates the step wherein the silicon nitride is removed leaving the oxide 804.

The geometries chosen were 1.2 μm, 2 μm, and 3 μm squares and lines (parallel and perpendicular to the laser trim beam direction) with the same space between for 50% loading of each node. FIG. 9 illustrates the various geometries. A brief description of each of the geometries is provided in the table below (Table 1):

TABLE 1

| | |
|---|---|
| R1 | 1.2 μm squares |
| R2 | 1.2 μm perpendicular lines |
| R3 | 1.2 μm parallel lines |
| R4 | 2 μm squares |
| R5 | 2 μm perpendicular |
| R6 | Active resistor |
| R7 | 3 μm parallel |
| R8 | 3 μm perpendicular |
| R9 | 3 μm squares |
| R10 | 2 μm parallel |

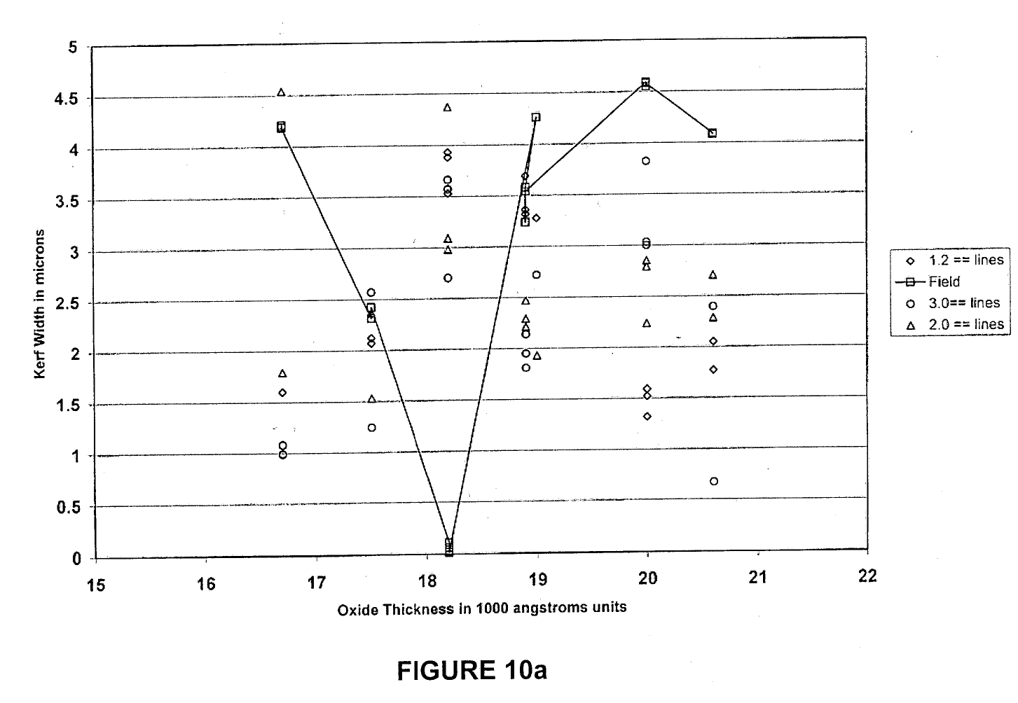

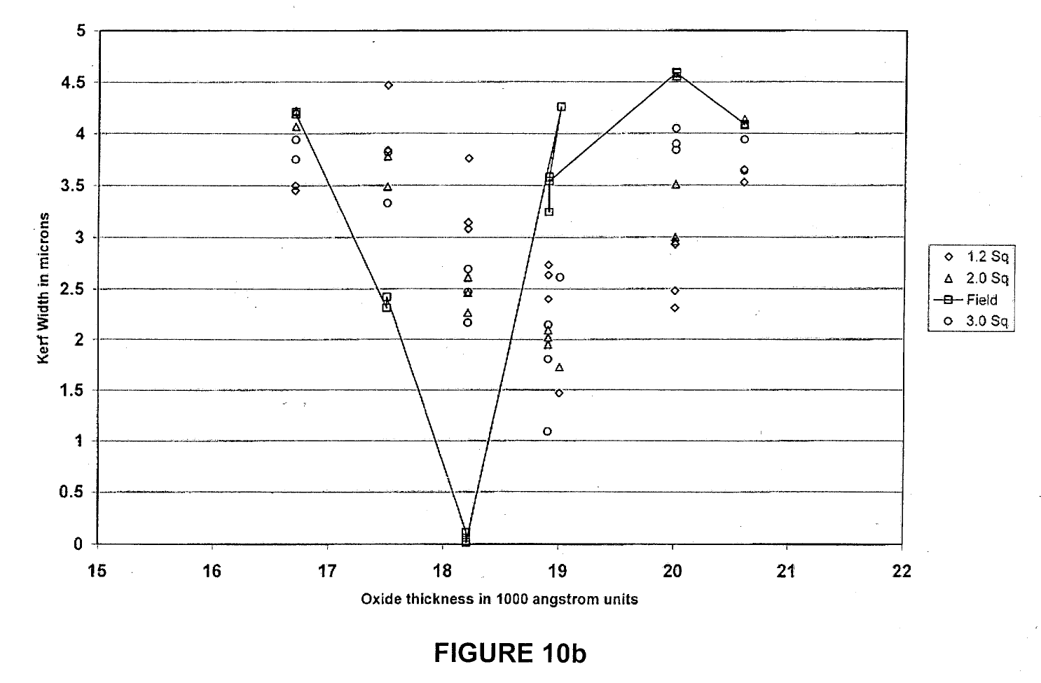

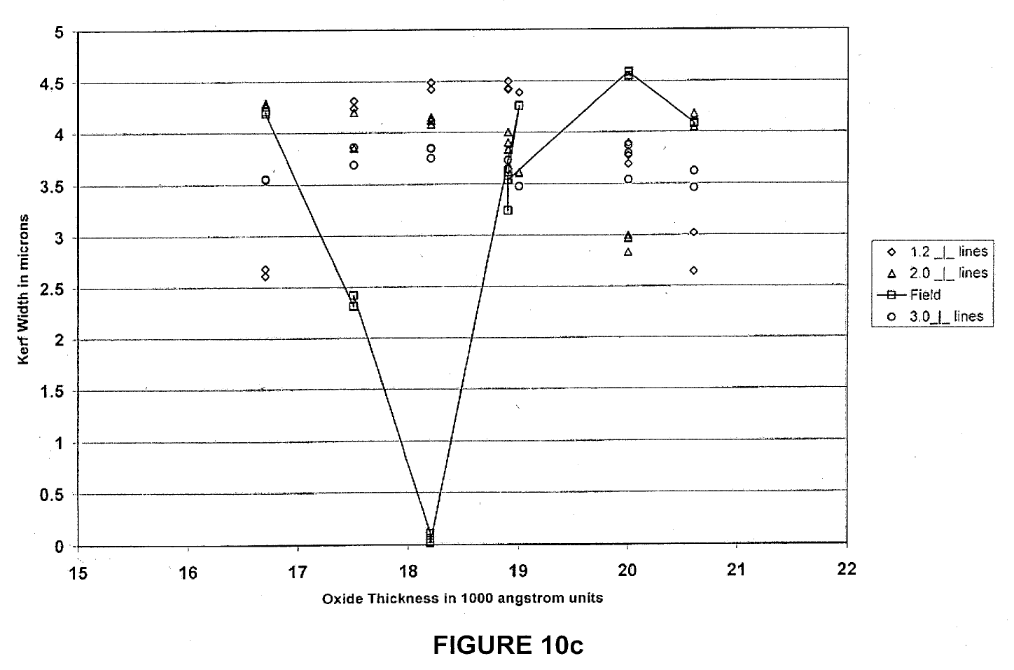

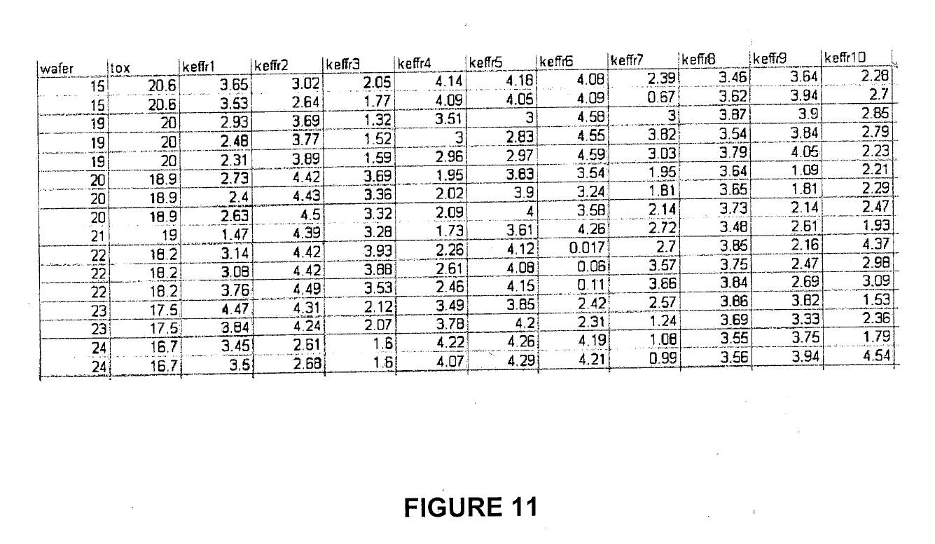

FIGS. 10a-c collectively illustrate the graphs of Kerf width versus Tox for various combinations of the above-mentioned geometries. Kerf width and Tox data corresponding to FIGS. 10a-c are provided for in the table in FIG. 11. The laser spot size is typically 5 to 6 microns in diameter. Therefore, trim kerfs that approach 5 microns and wider provide for the trims with the maximum energy at the trim plane. These structures have the most consistent and high Kerf due to the fact that it should present an uninterrupted trim along the full length of the resistor. Both square and perpendicular lines should show similar behavior if the local planarisation is good—and this by and large seems to be the case with functional trim in all cases, if at times very low.

What is claimed is:

1. A semiconductor device comprising:
a. a substrate, said substrate reflecting incident trimming laser waves;
b. an integrated circuit formed in said substrate;
c. a dielectric layer disposed over said substrate;
d. a trimmable thin film layer disposed over said dielectric layer, and said substrate having one or more steps, said one or more steps creating said incident and reflected trimming laser waves to form constructive nodes at said trimmable thin film layer.

2. A semiconductor device, as per claim 1, wherein device parameters associated with said semiconductor device are adjustable.

3. A semiconductor device, as per claim 1, wherein said substrate is Si.

4. A semiconductor device, as per claim 1, wherein said dielectric layer is SiO₂.

5. A semiconductor device, as per claim 1, wherein said steps ensure a laser path substantially equal to an odd multiple of a quarter wavelength associated with said trimming laser waves in said dielectric layer.

6. A semiconductor device, as per claim 1, wherein said trimmable thin film layer is a trimmable thin film resistor layer.

7. A semiconductor device, as per claim 6, wherein said semiconductor device is part of a precision resistor network.

8. A semiconductor device, as per claim 6, wherein said trimmable thin film resistor layer is any of the following: SiCr or NiCr.

9. A semiconductor device, as per claim 1, wherein said one or more steps are formed via etching.

10. A semiconductor device, as per claim 1, wherein said one or more steps are formed using any of the following techniques: shallow trench isolation mask, a separate etch step, or LOCOS.

11. A semiconductor device with a trimmable thin film resistor layer comprising:
a. a semiconductor device substrate, said semiconductor device substrate reflecting incident trimming laser waves;
b. an integrated circuit formed in said substrate;
c. an inter-metal dielectric layer disposed over said substrate;
d. a trimmable thin film resistor layer disposed over said inter-metal dielectric layer, and
said semiconductor device substrate having one or two steps, said steps creating said incident and reflected trimming laser waves to form constructive nodes at said trimmable thin film resistor layer.

12. A semiconductor device with a trimmable thin film resistor layer, as per claim 11, wherein device parameters associated with said semiconductor device are adjustable.

13. A semiconductor device with a trimmable thin film resistor layer, as per claim 11, wherein said semiconductor device substrate is Si.

14. A semiconductor device with a trimmable thin film resistor layer, as per claim 11, wherein said inter-metal dielectric layer is SiO₂.

15. A semiconductor device with a trimmable thin film resistor layer, as per claim 11, wherein said steps ensure a laser path substantially equal to an odd multiple of a quarter wavelength associated with said trimming laser waves in said inter-metal dielectric layer.

16. A semiconductor device with a trimmable thin film resistor layer, as per claim 11, wherein said trimmable thin film resistor layer is any of the following: SiCr or NiCr.

17. A semiconductor device with a trimmable thin film resistor layer, as per claim 11, wherein said semiconductor device is part of a precision resistor network.

18. A semiconductor device with a trimmable thin film resistor layer, as per claim 11, wherein said steps are formed via etching.

19. A semiconductor device with a trimmable thin film resistor layer, as per claim 11, wherein said one or more steps are formed using any of the following techniques: shallow trench isolation mask, a separate etch step, or LOCOS.

20. A semiconductor device with a trimmable thin film resistor layer comprising:
a. a silicon substrate, said silicon substrate reflecting incident trimming laser waves;
b. an integrated circuit formed in said silicon substrate;
c. an silicon oxide dielectric layer disposed over said silicon substrate;
d. a trimmable thin film SiCr resistor layer disposed over said silicon oxide dielectric layer, and
said silicon substrate having one or two steps, said steps creating said incident and reflected trimming laser waves to form constructive nodes at said trimmable thin film SiCr resistor layer.

21. A semiconductor device with a trimmable thin film resistor layer, as per claim 20, wherein device parameters associated with said semiconductor device are adjustable.

22. A semiconductor device with a trimmable thin film resistor layer, as per claim 20, wherein said steps ensure a laser path substantially equal to an odd multiple of a quarter wavelength associated with said trimming laser waves in said silicon dioxide dielectric layer.

23. A semiconductor device with a trimmable thin film resistor layer, as per claim 20, wherein said steps are formed via etching.

24. A semiconductor device with a trimmable thin film resistor layer, as per claim 23, wherein said one or more steps are formed using any of the following techniques: shallow trench isolation mask, a separate etch step, or LOCOS.

25. A semiconductor device with a trimmable thin film resistor layer, as per claim 20, wherein said semiconductor device is part of a precision resistor network.

26. A method for forming a semiconductor device having a trimmable thin film layer, said method comprising the steps of:
a. forming a substrate with one or more steps;
b. forming an integrated circuit in said substrate;
c. forming a dielectric layer disposed over said substrate;
d. forming a trimmable thin film layer disposed over said dielectric layer;
e. trimming said thin film layer via incident trimming laser waves, said incident laser waves reflected by said steps in said substrate, and
said steps in said substrate creating said incident and reflected trimming laser waves to form constructive nodes at said trimmable thin film layer.

27. A method for forming a semiconductor device having a trimmable thin film layer, as per claim 26, wherein said step of trimming said thin film layer adjusts device parameters associated with said semiconductor device.

28. A method for forming a semiconductor device having a trimmable thin film layer, as per claim 26, wherein said substrate is Si.

29. A method for forming a semiconductor device having a trimmable thin film layer, as per claim 26, wherein said dielectric layer is SiO₂.

30. A method for forming a semiconductor device having a trimmable thin film layer, as per claim 26, wherein said steps ensure a laser path substantially equal to an odd multiple of a quarter wavelength associated with said trimming laser waves.

31. A method for forming a semiconductor device having a trimmable thin film layer, as per claim 26, wherein said trimmable thin film layer is a trimmable thin film resistor layer.

32. A method for forming a semiconductor device having a trimmable thin film layer, as per claim 31, wherein said trimmable thin film resistor layer is any of the following: SiCr or NiCr.

33. A method for forming a semiconductor device having a trimmable thin film layer, as per claim 26, wherein said semiconductor device is part of a precision resistor network.

34. A method for forming a semiconductor device having a trimmable thin film layer, as per claim 26, wherein said one or more steps are formed via etching.

35. A method for forming a semiconductor device having a trimmable thin film layer, as per claim 26, wherein said one or more steps are formed using any of the following techniques: shallow trench isolation mask, a separate etch step, or LOCOS.

36. A semiconductor device comprising:
a. a substrate, said substrate reflecting incident trimming laser waves;
b. an integrated circuit formed in said substrate;
c. a dielectric layer disposed over said substrate;
d. a trimmable thin film layer disposed over said dielectric layer, and
said substrate having one or more steps, said one or more steps preventing said incident and reflected trimming laser waves from forming destructive nodes at said trimmable thin film layer.

37. A semiconductor device with a trimmable thin film resistor layer comprising:
a. a semiconductor device substrate, said semiconductor device substrate reflecting incident trimming laser waves;
b. an integrated circuit formed in said substrate;
c. an inter-metal dielectric layer disposed over said substrate;
d. a trimmable thin film resistor layer disposed over said inter-metal dielectric layer, and
said semiconductor device substrate having one or two steps, said steps preventing said incident and reflected trimming laser waves from forming destructive nodes at said trimmable thin film resistor layer.

38. A semiconductor device with a trimmable thin film resistor layer comprising:
a. a silicon substrate, said silicon substrate reflecting incident trimming laser waves;
b. an integrated circuit formed in said silicon substrate;
c. an silicon oxide dielectric layer disposed over said silicon substrate;
d. a trimmable thin film SiCr resistor layer disposed over said silicon oxide dielectric layer, and
said silicon substrate having one or two steps, said steps preventing said incident and reflected trimming laser waves from forming destructive nodes at said trimmable thin film SiCr resistor layer.

39. A method for forming a semiconductor device having a trimmable thin film layer, said method comprising the steps of:
a. forming a substrate with one or more steps;
b. forming an integrated circuit in said substrate;
c. forming a dielectric layer disposed over said substrate;
d. forming a trimmable thin film layer disposed over said dielectric layer;
e. trimming said thin film layer via incident trimming laser waves, said incident laser waves reflected by said steps in said substrate, and
said steps in said substrate preventing said incident and reflected trimming laser waves from forming destructive nodes at said trimmable thin film layer.
